(19) United States
(12) Patent Application Publication
(10) Pub. No.: US 2024/0012189 A1
(43) Pub. Date: Jan. 11, 2024

(54) POLARIZER AND MANUFACTURING METHOD THEREOF, DISPLAY PANEL AND DISPLAY APPARATUS

(71) Applicant: BOE Technology Group Co., Ltd., Beijing (CN)

(72) Inventors: Duohui LI, Beijing (CN); Zheng DUAN, Beijing (CN); Xiao ZHANG, Beijing (CN); Mengya SONG, Beijing (CN); Zhen LIU, Beijing (CN); Yong MA, Beijing (CN); Kang GUO, Beijing (CN); Xin GU, Beijing (CN)

(21) Appl. No.: 17/619,807

(22) PCT Filed: Feb. 25, 2021
(86) PCT No.: PCT/CN2021/077932

§ 371 Date: Dec. 16, 2021

(51) Int. Cl. G02B 5/30; G02B 1/11

(52) U.S. Cl. CPC G02B 5/3025; G02B 1/11

(57) ABSTRACT

The present application provides a polarizer, a manufacturing method thereof, a display panel and a display apparatus. The polarizer includes an antireflection layer, a first support layer and a grating layer stacked in sequence along a light incidence direction. The grating layer includes a plurality of first grating strips spaced apart. The first support layer includes a plurality of first support strips spaced apart and a plurality of second support strips disposed between any two adjacent first support strips, and the first support strips are disposed corresponding to the first grating strips. The antireflection layer includes a plurality of second grating strips spaced apart, and the second grating strips are disposed corresponding to the first grating strips. The antireflection layer, the first support layer and the grating layer form an optical resonant cavity structure, or, the antireflection layer is configured to absorb light reflected by the grating layer. A display panel includes the polarizer. A display apparatus includes the display panel.

### TECHNICAL FIELD

The present disclosure relates to the field of display technologies, and in particular to a polarizer, and a manufacturing method thereof, a display panel and a display apparatus.

### BACKGROUND

In the prior art, a traditional iodine polarizer is one of core devices of a display component. However, due to its non-resistance to high temperature, the iodine polarizer is not compatible with many processes, which limits the development of display devices.

In order to reduce device costs and increase polarizer durability, the traditional iodine polarizer is replaced with a more durable wire grid polarizer (WGP). The wire grid polarizer is formed by a group of regularly-arranged sub-wavelength metal wire grids, which destroys metallicity in a direction perpendicular to wire grid to some extent. The wire grid polarizer has the following optical characteristics: linearly polarized light parallel to metal wire grid can be reflected and linearly polarized light perpendicular to metal wire grid can be transmitted. Such nano-level wire grid polarizer is usually made of aluminum. Compared with other materials, aluminum has higher reflective index and lower cost.

However, the linearly polarized light parallel to metal wire grid will be reflected on a surface of the metal wire grid polarizer, and the light reflected from the wire grid polarizer will reduce a display quality of an image.

### SUMMARY

The present application provides a polarizer, and a manufacturing method thereof, a display panel and a display apparatus. With provision of a specific structure of the polarizer, reflective index will be greatly reduced, display quality will be improved, and a structure of the polarizer will be made more stable at the same time.

According to a first aspect of embodiments of the present disclosure, provided is a polarizer. The polarizer includes an antireflection layer, a first support layer, and a grating layer stacked in sequence along a light incidence direction;
the grating layer includes a plurality of first grating strips disposed along a first direction and the plurality of first grating strips are spaced apart;
the first support layer includes a plurality of first support strips disposed along the first direction and spaced apart and a plurality of second support strips disposed between any two adjacent first support strips along a second direction, where the second direction and the first direction form an included angle which is greater than 0 degrees and smaller than 180 degrees, and the first support strips are disposed corresponding to the first grating strips;
the antireflection layer includes a plurality of second grating strips disposed along the first direction, the plurality of second grating strips are spaced apart, positions of the second grating strips are set corresponding to positions of the first grating strips, and third gaps are formed between any two adjacent second grating strips;
the antireflection layer, the first support layer and the grating layer form an optical resonant cavity structure, or, the antireflection layer is configured to absorb light reflected by the grating layer.

Optionally, the second direction is perpendicular to the first direction; and/or,
at least part of the second support strips located between different sets of two adjacent first support strips are located along a same straight line; and/or,
the second support strips located between different sets of two adjacent first support strips are not located along a same straight line.

Optionally, a duty cycle of the grating layer is 0.3-0.6; and/or,
a height of the grating layer is greater than a height of the first support layer, and the height of the first support layer is greater than a height of the antireflection layer; and/or,
the height of the grating layer is 100 nm-250 nm, the height of the first support layer is 70 nm-200 nm, and the height of the antireflection layer is 5 nm-100 nm.

Optionally, along the light incidence direction, an orthographic projection of a first support strip is at least partially overlapped with an orthographic projection of a first grating strip corresponding to the first support strip; along the light incidence direction, an orthographic projection of the first support strip is at least partially overlapped with an orthographic projection of the first grating strip corresponding to the first support strip;
along the light incidence direction, a distance of an orthographic projection of a side of the first support strip and an orthographic projection of a side of the first grating strip corresponding to the first support strip is smaller than or equal to 40 nm, and a distance of an orthographic projection of a side of the second grating strip and an orthographic projection of a side of the first grating strip corresponding to the second grating strip is smaller than or equal to 20 nm.

Optionally, the grating layer is made of a metal material; and the first support layer is made of a transparent material.

Optionally, the polarizer includes a second support layer located at a side of the antireflection layer away from the first support layer, the second support layer includes a plurality of third support strips disposed along the first direction and spaced apart and a plurality of fourth support strips disposed between any two adjacent third support strips along the second direction, and positions of the third support strips are set corresponding to positions of the first grating strips; and/or,
the fourth support strips are disposed corresponding to the second support strips; and/or,
the second support layer is made of a transparent material.

Optionally, the polarizer further includes a substrate, and the substrate is located at a side of the grating layer away from the first support layer or at a side of the antireflection layer away from the first support layer.

According to a second aspect of embodiments of the present application, provided is a polarizer manufacturing method used to prepare the above polarizer. The polarizer manufacturing method includes:
forming the grating layer on a substrate;
forming the first support layer on the grating layer; and
forming the antireflection layer on the first support layer.

Optionally, after the antireflection layer is formed on the first support layer, the method further includes: forming a second support layer on the antireflection layer, where the second support layer includes a plurality of third support strips disposed along the first direction and spaced apart and a plurality of fourth support strips disposed between any two adjacent third support strips along the second direction, and position of the third support strips are set corresponding to positions of the first grating strips; and/or,
the fourth support strips are disposed corresponding to the second support strips; and/or,
the second support layer is made of a transparent material.

According to a third aspect of embodiments of the present application, provided is a polarizer manufacturing method used to prepare the above polarizer. The polarizer manufacturing method includes:
forming the antireflection layer on a substrate;
forming the first support layer on the antireflection layer; and
forming the grating layer on the first support layer.

Optionally, before the antireflection layer is formed on the transparent substrate, the method further includes: forming a second support layer on the substrate, where the second support layer includes a plurality of third support strips disposed along the first direction and spaced apart and a plurality of fourth support strips disposed between any two adjacent third support strips along the second direction, and positions of the third support strips are set corresponding to positions of the first grating strips; and/or,
the fourth support strips are disposed corresponding to the second support strips; and/or,
the second support layer is made of a transparent material.

According to a third aspect of embodiments of the present application, provided is a display panel including the above polarizer.

According to a fourth aspect of embodiments of the present application, provided is a display apparatus including the above display panel.

In the polarizer, and the manufacturing method thereof, the display panel and the display apparatus in the present application, with provision of a specific structure of the polarizer, reflective index will be greatly reduced, display quality will be improved, and a structure of the polarizer will be made more stable at the same time.

In the present application, the polarizer may achieve the effect of reducing reflective index in two manners. The reflective index of the polarizer to ambient light is reduced to prevent the reflected ambient light from affecting display quality of an image. In the present application, the polarizer includes the antireflection layer, the first support layer and the grating layer stacked in sequence along the light incidence direction, where the light herein refers to ambient light.

In a first manner, the antireflection layer, the first support layer and the grating layer form an optical resonant cavity structure. Specifically, white light enters the polarizer from an incidence direction, is transmitted through the antireflection layer and the first support layer, then reflected on a surface of the grating layer and then emitted from a side of the antireflection layer away from the first support layer, thus achieving reflection of light of a particular color and reducing entire reflective index of the polarizer. The first support layer between the antireflection layer and the grating layer is a dielectric layer and serves as a matching layer to induce the reflective index of a film system near a particular wavelength to maximum. Because optical property of this structure is sensitive to a thickness of the first support layer, reflection of light of different colors can be induced simply by changing the thickness of the first support layer. It should be noted that in this structure, the first support layer may not only serve as a part of the optical resonant cavity structure but also serve a good supporting effect by arranging specific structure of the first support layer 20, that is, a plurality of first support strips disposed along the first direction and spaced apart and a plurality of second support strips disposed between any two adjacent first support strips along the second direction, thereby making the entire structure of the polarizer more stable.

In a second manner, light reflected by the grating layer is directly absorbed by the antireflection layer to achieve lowering of reflective index. It is to be noted that in this structure, the first support layer can not only achieve a good supporting effect to make the entire structure of the polarizer more stable; but also at the same time, separate the absorption layer and the grating layer since the first support layer is located between the antireflection layer and the grating layer so as to avoid mutual influence between absorption effect of the antireflection layer and polarization effect of the grating layer.

### BRIEF DESCRIPTION OF THE DRAWINGS

FIG. 1 is a structural schematic diagram of a top view of a polarizer according to embodiment 1 of the present disclosure.

FIG. 2 is a schematic diagram of a sectional structure taken along A-A in FIG. 1.

FIG. 3 is a schematic diagram of a sectional structure taken along B-B in FIG. 1.

FIG. 4 is a schematic diagram of a sectional structure taken along C-C in FIG. 1.

FIG. 5 is a structural schematic diagram of a top view of a grating layer of a polarizer according to embodiment 1 of the present disclosure.

FIG. 6 is a structural schematic diagram of a top view of a first support layer of a polarizer according to embodiment 1 of the present disclosure.

FIG. 7 is a structural schematic diagram of a top view of another implementation of a first support layer of a polarizer according to embodiment 1 of the present disclosure.

FIGS. 8-11 are structural schematic diagrams of sequentially-stacked layers of a polarizer according to embodiment 1 of the present disclosure.

FIG. 12 is a sectional structural diagram of another implementation of a polarizer according to embodiment 1 of the present disclosure.

FIGS. 13-22 are process flows of a polarizer manufacturing method according to embodiment 1 of the present disclosure.

FIG. 23 is a sectional structural diagram of a polarizer according to embodiment 2 of the present disclosure.

FIG. 24 is a sectional structural diagram of another implementation of a polarizer according to embodiment 2 of the present disclosure.

### DETAILED DESCRIPTION OF THE EMBODIMENTS

Exemplary embodiments will be described in detail herein with the examples thereof expressed in the drawings. When the following descriptions involve the drawings, like numerals in different drawings represent like or similar elements unless stated otherwise. The implementations described in the following exemplary embodiments do not represent all implementations consistent with the present disclosure. On the contrary, they are merely examples of an apparatus and a method consistent with some aspects of the present disclosure described in detail in the appended claims.

Terms used herein are used to only describe a particular embodiment rather than limit the present disclosure. Unless otherwise defined, technical terms or scientific terms used in the present disclosure should have general meanings that can be understood by ordinary persons of skill in the art. “One” or “a” and the like in the specification and the claims do not represent quantity limitation but represent at least one. Unless otherwise stated, “include” or “contain” or the like is intended to refer to that an element or object appearing before “include” or “contain” covers an element or object or its equivalents listed after “include” or “contain” and does not preclude other elements or objects. “Connect” or “connect with” or the like is not limited to physical or mechanical connection but includes direct or indirect electrical connection. “Multiple” includes two and is equivalent to at least two. The words, “a”, ‘said”, and “the” in the singular form used in the specification and the appended claims are also intended to include multiple, unless the context clearly indicates otherwise. It is also to be understood that the term “and/or” as used herein refers to any or all possible combinations that include one or more associated listed items.

### Embodiment 1

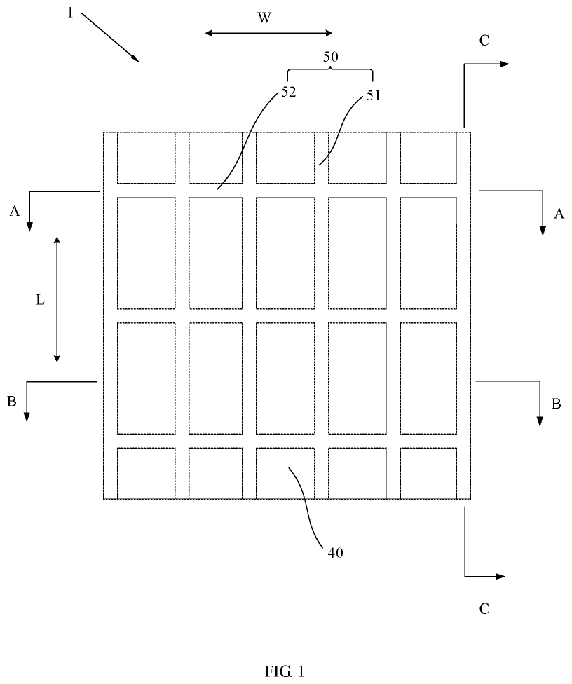

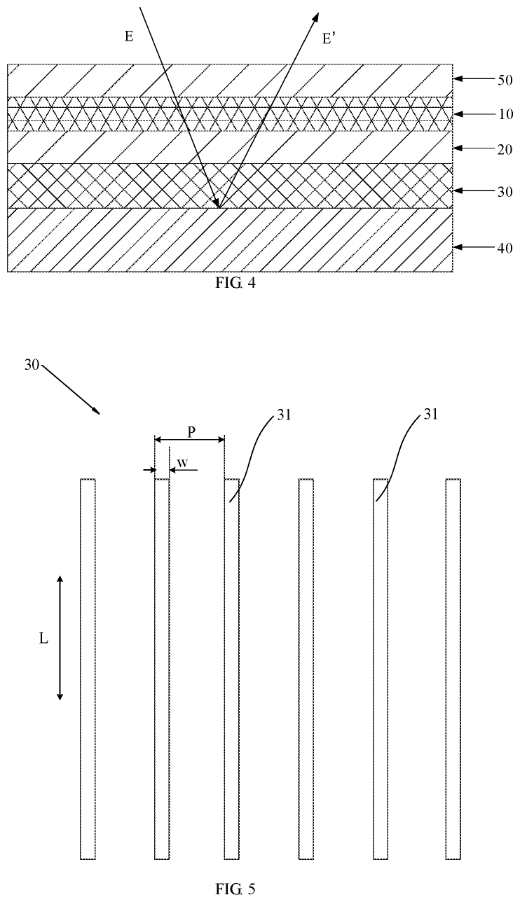

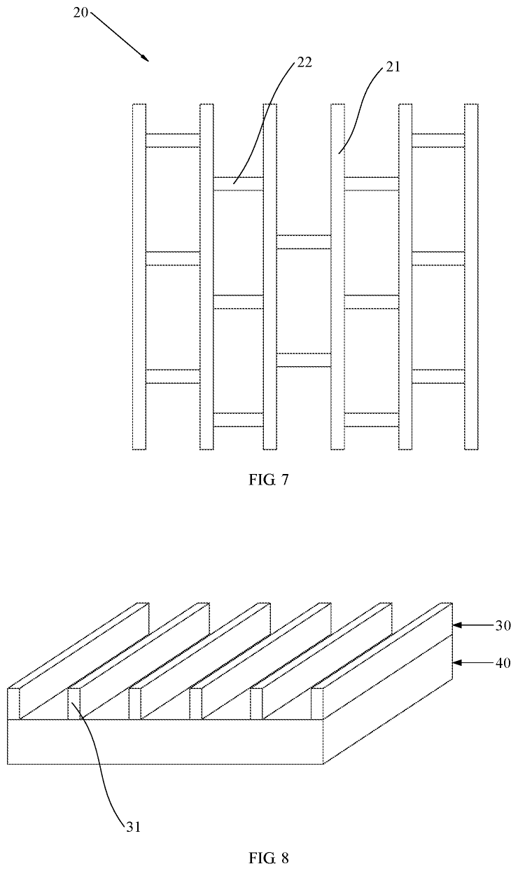

Please comprehend in combination with FIGS. 1-7, the embodiment provides a polarizer 1. The polarizer 1 includes an antireflection layer 10, a first support layer 20, a grating layer 30 and a substrate 40 stacked in sequence along a light incidence direction F. The substrate 40 is located at a side of the grating layer 30 away from the first support layer 20. The substrate 40 is a transparent substrate. The substrate 40 may be made of glass, quartz, PI, or PET or the like, which is not limited herein.

The grating layer 30 includes a plurality of first grating strips 31 disposed along a first direction L and the plurality of first grating strips 31 are spaced apart. That is, each of the plurality of first grating strips 31 is disposed along the first direction L and the plurality of first grating strips 31 are spaced apart.

The first support layer 20 includes a plurality of first support strips 21 disposed along the first direction L and spaced apart (that is, each of the plurality of first support strips 21 is disposed along the first direction L and the plurality of first support strips 21 are spaced apart) and a plurality of second support strips 22 disposed between two adjacent first support strips 21 along a second direction W. The second direction W and the first direction L form an included angle (i.e. the second direction W is not parallel to the first direction L). That is, the first support strip 21 and the second support strip 22 form an included angle α which is greater than 0 degree and smaller than 180 degrees. Positions of the first support strips 21 are set corresponding to positions of the first grating strips 31. The first support layer 20 is integrally formed, that is, the first support strips 21 and the second support strips 22 are integrally formed.

The antireflection layer 10 includes a plurality of second grating strips 11 disposed along the first direction L and spaced apart, and positions of the second grating strips 11 are set corresponding to positions of the first grating strips 31. That is, each of the plurality of second grating strips 11 is disposed along the first direction L and the plurality of second grating strips 11 are spaced apart.

In this embodiment, the included angle α formed by the second direction W and the first direction L is equal to 90 degrees, that is, the second direction W (a direction in which the second support strips 22 are disposed) is perpendicular to the first direction L (a direction in which the first support strips 21 are disposed). The second support strips 22 are perpendicular to the first support strips 21 to facilitate manufacturing process. A width w2 of the second support strip 22 is 20 nm-200 nm.

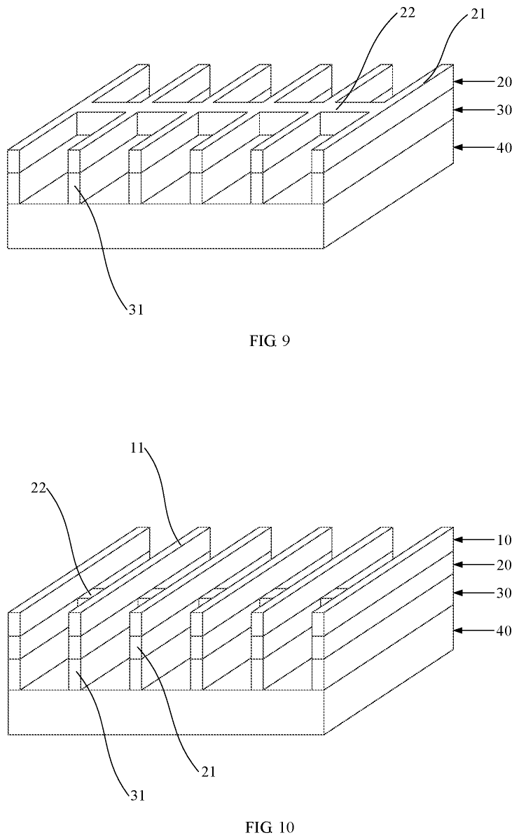

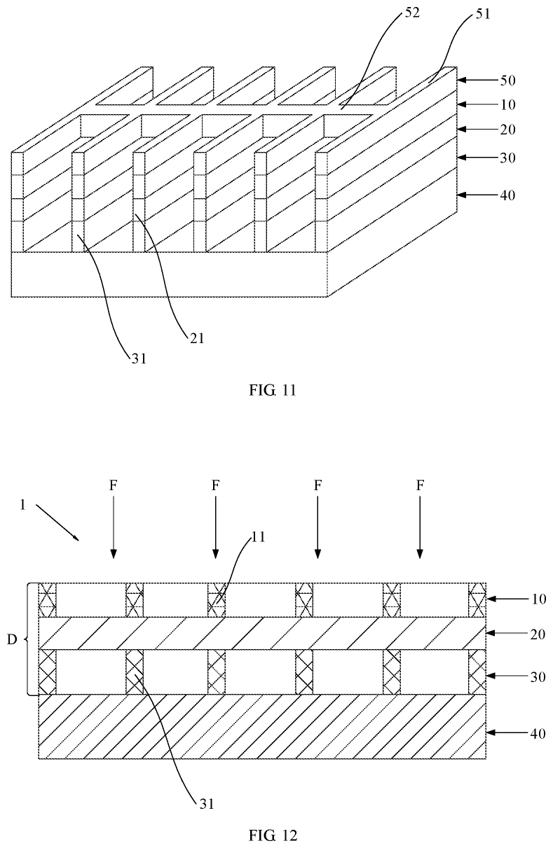

As shown in FIG. 6, the second support strips 22 located between different sets of two adjacent first support strips 21 may be located along a same straight line. As shown in FIG. 7, in another implementation, a part of the second support strips 22 located between different sets of two adjacent first support strips 21 may be located along a same straight line and another part of the second support strips 22 are located along another straight line. In another embodiment, alternatively, any two of the second support strips 22 located between different sets of two adjacent first support strips 21 are not located along a same straight line.

The number of the second support strips 22 located between two adjacent first support strips 21 may be multiple to realize better supporting effect. The plurality of second support strips 22 between two adjacent first support strips 21 may be disposed at intervals to achieve better supporting effect.

In an embodiment, a period/pitch p of the grating layer 30 is 100 nm-140 nm, and in another embodiment, the period p may be 100 nm, 120 nm or 140 nm. A duty cycle of the grating layer 30 is 0.3-0.6, where the duty cycle is a ratio of the first grating strip 31 in the period p of the grating layer 30, i.e., a ratio of a width w of the first grating strip 31 to a length of one period p of the grating layer 30. The ratio of the width w of the first grating strip 31 to the period p of the grating layer 30 is w/p.

A height h1 of the grating layer is greater than a height h2 of the first support layer, and the height h2 of the first support layer is greater than a height h3 of the antireflection layer. The height h1 of the grating layer is 100 nm-250 nm, the height h2 of the first support layer is 10 nm-200 nm, and the height h3 of the antireflection layer is 5 nm-100 nm.

In this embodiment, along the light incidence direction F, an orthographic projection of the first support strip 21 is fully overlapped with an orthographic projection of the first grating strip 31 corresponding to the first support strip 21. Along the light incidence direction F, an orthographic projection of the second grating strip 11 is fully overlapped with an orthographic projection of the first grating strip 31 corresponding to the second grating strip 11. In this case, influence on the polarization effect of the polarizer 1 can be avoided as possible.

However, the embodiment is not limited thereto. Optionally, along the light incidence direction F, the orthographic projection of the first support strip 21 is at least partially overlapped with the orthographic projection of the first grating strip 31 corresponding to the first support strip 21; along the light incidence direction F, the orthographic projection of the second grating strip 11 is at least partially overlapped with the orthographic projection of the first grating strip 31 corresponding to the second grating strip 11. In an embodiment, along the light incidence direction F, a distance of an orthographic projection of a side of the first support strip 21 and an orthographic projection of a side of the first grating strip 31 corresponding to the first support strip 21 is smaller than or equal to 40 nm, and a distance of an orthographic projection of a side of the second grating strip 11 and an orthographic projection of a side of the first grating strip 31 corresponding to the second grating strip 11 is smaller than or equal to 20 nm. That is, the first support strip 21 is slightly shifted relative to the first grating strip 31, and the second grating strip 11 is slightly shifted relative to the first grating strip 31.

In this embodiment, the antireflection layer 10, the first support layer 20 and the grating layer 30 form an optical resonant cavity structure, or the antireflection layer 10 is used to absorb light reflected by the grating layer 30.

In other words, the polarizer 1 in the present disclosure may achieve the effect of reducing reflective index in two manners. The reflective index of the polarizer 1 to ambient light is reduced to prevent the reflected ambient light from affecting display quality of an image. In the present disclosure, the polarizer 1 includes the antireflection layer 10, the first support layer 20 and the grating layer 30 stacked in sequence along the light incidence direction F, where the light herein refers to ambient light.

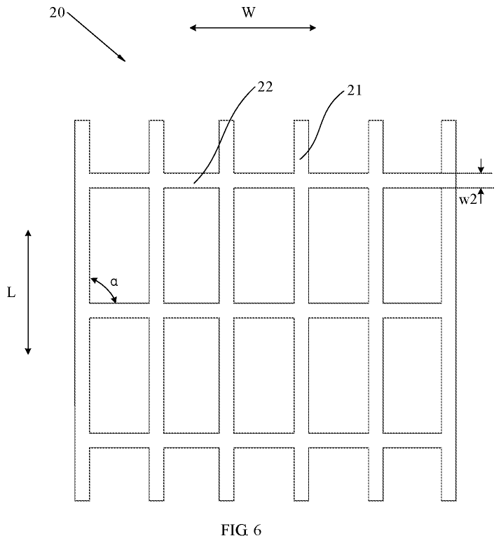

In a first manner, the antireflection layer 10, the first support layer 20 and the grating layer 30 form an optical resonant cavity structure D. Specifically, as shown in FIG. 4, the direction E indicated by an arrow is a light path direction. White light enters the polarizer 1 along the direction E indicated by an arrow (light incidence direction), is transmitted through the antireflection layer 10 and the first support layer 20 and then reflected on a surface of the grating layer 30 and then emitted from a side of the antireflection layer 10 away from the first support layer 20 along the direction E′ indicated by an arrow, thus achieving light reflection of a particular color and reducing overall reflective index of the polarizer 1. The first support layer 20 between the antireflection layer 10 and the grating layer 30 is a dielectric layer which serves as a matching layer to induce the reflective index of a film system near a particular wavelength to maximum. Because optical property of this structure is sensitive to a thickness of the first support layer 20, reflection of light of different colors can be induced simply by changing the thickness of the first support layer 20. It should be noted that in this structure, the first support layer 20 may not only serve as a part of the optical resonant cavity structure but also serve a good supporting effect by arranging specific structure of the first support layer 20, that is, a plurality of first support strips 21 disposed along the first direction and spaced apart and a plurality of second support strips 22 disposed between two adjacent first support strips 21 along the second direction, making the entire structure of the polarizer 1 more stable. The grating layer 30 may be made of a metal material, such as aluminum, silver, platinum, gold or metallic compound. The first support layer 20 may be made of a transparent material such as silicon oxide. A reflective index of the grating layer 30 is greater than that of the antireflection layer 10, and a transmittance of the grating layer 30 is smaller than that of the antireflection layer 10. The antireflection layer 10 may be made of a metal material such as chromium, titanium or molybdenum, or may be made of a non-metal material such as ceramic material, i.e. a composite material prepared by mixing nano-level metal particles in silicon oxide and the like.

In a second manner, light reflected by the grating layer 30 can be directly absorbed by the antireflection layer 10 to achieve an effect of lowering reflective index. It is to be noted that in this structure, the first support layer 20 can not only serve a good supporting effect to make the entire structure of the polarizer 1 more stable; but also at the same time, separate the absorption layer and the grating layer 30 since the first support layer 20 is located between the antireflection layer 10 and the grating layer 30 so as to avoid mutual influence between absorption effect of the antireflection layer 10 and polarization effect of the grating layer 30. The grating layer 30 and the first support layer respectively are made of the same material as described in the first manner, but the antireflection layer 10 for absorbing light reflected by the grating layer 30 is made of a metal oxide such as copper oxide or chromium oxide.

Furthermore, it is to be noted that the first support layer 20 has a prominent supporting effect when the polarizer 1 according to the embodiment is a wire grid polarizer (WGP) because the metal grating (the first grating strips 31 of the grating layer in the wire grid polarizer is a nano-level wire grid structure and providing a structure on the metal grating will easily generate a problem of toppling, thus leading to unstable entire structure.

In this embodiment, the polarizer 1 further includes a second support layer 50 located at a side of the antireflection layer 10 away from the first support layer 20. The second support layer 50 includes a plurality of third support strips 51 disposed along the first direction and spaced apart and a plurality of fourth support strips 52 disposed between two adjacent third support strips 51 along the second direction W. Positions of the third support strips 51 are set corresponding to positions of the first grating strips 31. The fourth support strips 52 are disposed corresponding to the second support strips 22. The second support layer 50 is integrally formed, that is, the third support strips 51 and the fourth support strips 52 are integrally formed.

Thus, with provision of the second support layer 50, the supporting effect can be further increased and the stability of the entire structure can be enhanced. Furthermore, the second support layer 50 is located on a side of the antireflection layer 10 away from the first support layer 20, that is, light is incident to the antireflection layer 10 via the second support layer 50. Therefore, blocking matching can be realized and more light is allowed to enter the antireflection layer 10. The second support layer 50, the antireflection layer 10, the first support layer 20 and the grating layer 30 form an optical resonant cavity structure D which can reduce reflection of the incident light, thus greatly reducing the reflective index and improving the display quality of an image.

Along the light incidence direction, an orthographic projection of the fourth support strip 52 is fully overlapped with an orthographic projection of the second support strip 22 corresponding to the fourth support strip 52 so as to avoid affecting the polarization effect of the polarizer 1. However, the embodiment is not limited thereto. Alternatively, the orthographic projection of the fourth support strip 52 may be partially overlapped with the orthographic projection of the second support strip 22 corresponding to the fourth support strip 52. A width of the fourth support strip 52 is 20 nm-200 nm.

The second support layer 50 may be made of a transparent material. The second support layer 50 and the first support layer 20 may be made of a same material or different materials. In this embodiment, the second support layer 50 and the first support layer 20 are made of silicon oxide.

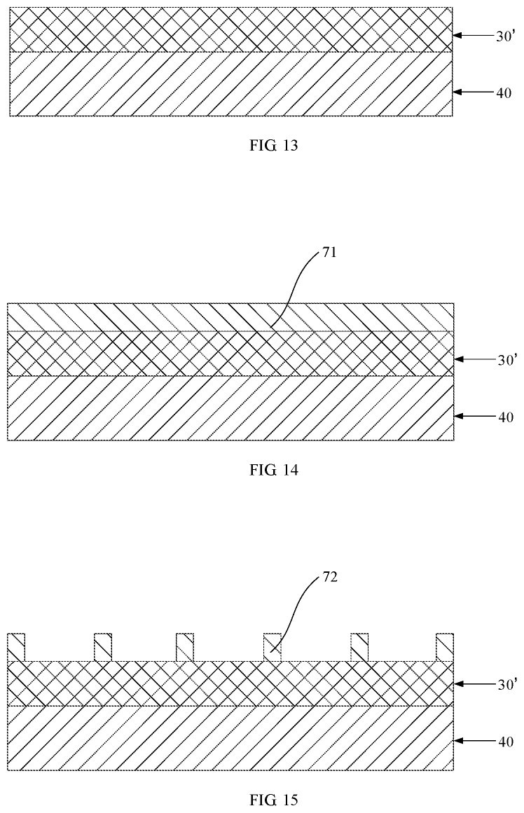

In order to better show structures of different layers of the polarizer 1 according to this embodiment, FIGS. 8-11 show structural schematic diagrams of different layers stacked in sequence.

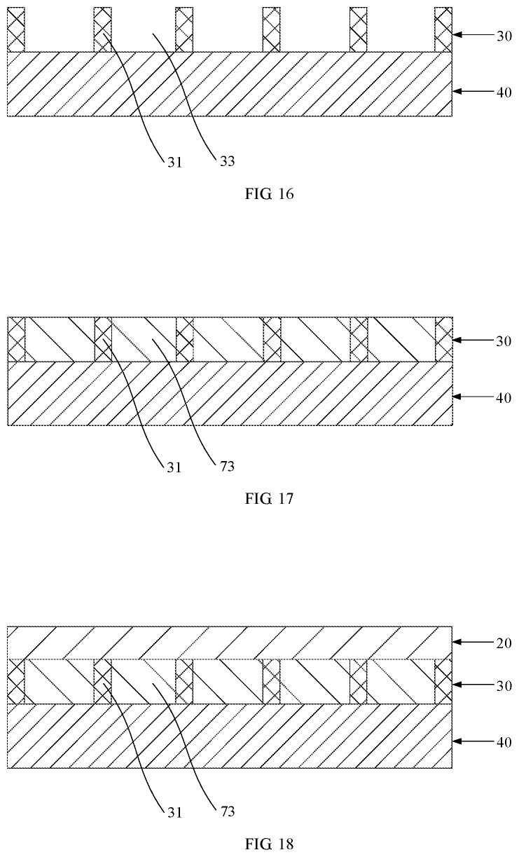

As shown in FIG. 12, in another implementation of the embodiment, the polarizer may not include the second support layer 50.

In this embodiment, with provision of a specific structure of the polarizer 1, the structure of the polarizer will be made more stable while reflective index is greatly reduced and display quality of image is improved. Experiment proves that a degree of polarization of the polarizer 1 in this embodiment is in the range of 99.9%-99.999%, a transmittance decreases by 5%-10%, and the reflective index decreases from greater than 40% to smaller than 10%.

This embodiment further provides a polarizer manufacturing method used to prepare the above polarizer 1. The polarizer manufacturing method includes the following steps.

At step 100, a grating layer is formed on a substrate.

At step 200, a first support layer is formed on the grating layer.

At step 300, an antireflection layer is formed on the first support layer.

At step 400, a second support layer is formed on the antireflection layer.

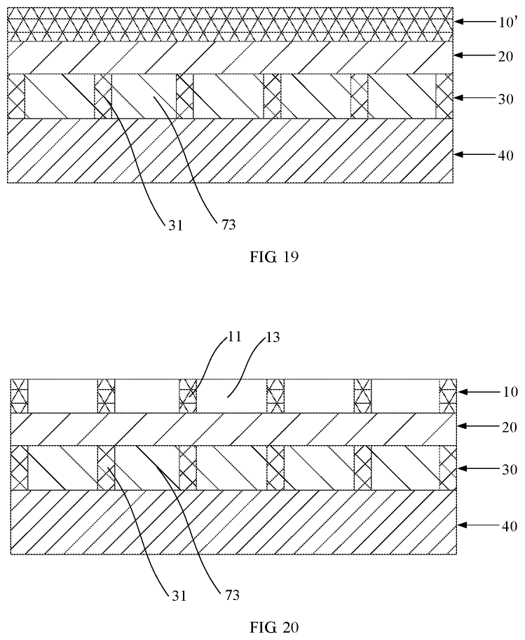

Specifically, as shown in FIGS. 13-22, the polarizer 1 manufacturing method according to this embodiment includes the followings.

At step 100, forming the grating layer 30 on the substrate 40 includes: as shown in FIG. 13, depositing a grating material layer 30′ on a surface of a side of the transparent substrate 40; next, as shown in FIG. 14, forming a photoresist layer 71 on the grating material layer 30′; next, as shown in FIG. 15, forming a photoresist grating 72 by patterning the photoresist layer 71; next, as shown in FIG. 16, forming the first grating strips 31 of the grating layer 30 by etching the grating material layer 30′ not covered by the photoresist grating 72, and first gaps 33 are formed between any two adjacent first grating strips 31; finally, washing off the photoresist grating 72 using a stripping solution. In an embodiment, the photoresist layer 71 may be patterned by using lithography equipment, and further, the photoresist layer 71 may be patterned by using a dry etching technology (for example, inductively coupled plasma (ICP) etch technology).

However, the embodiment is not limited thereto. Alternatively, the photoresist may be replaced with a nanoimprint resist to achieve the patterning. In the embodiment, the photoresist and the nanoimprint resist are both commercially available.

At step 200, forming the first support layer 20 on the grating layer 30 includes: as shown in FIG. 17, filling a photoresist material 73 between any two adjacent first grating strips 31 of the grating layer 30 (that is, filling the photoresist material 73 in the first gaps 33 formed between any two adjacent first grating strips 31), and curing the photoresist material 73 in such a way that an upper surface of the photoresist material 73 and an upper surface of the first grating strips 31 are located in a same horizontal plane; then, as shown in FIG. 18, forming a first support material layer on the upper surfaces of the first grating strips 31 and the photoresist material 73 and then patterning the first support material layer to form the first support layer 20. It is to be noted that the photoresist material 73 may be filled between any two adjacent first grating strips 31 of the grating layer 30 by coating or printing.

At step 300, forming the antireflection layer 10 on the first support layer 20 includes: filling the photoresist material 73 between any two adjacent first support strips 21 of the first support layer 20 (that is, filling the photoresist material 73 in second gaps (not shown) formed between any two adjacent first support strips 21) and curing the photoresist material 73 in such a way that an upper surface of the photoresist material 73 and an upper surface of the first support strips 21 are located in a same horizontal plane; next, as shown in FIG. 19, forming an absorption material layer 10′ on the upper surfaces of the first support strips 21 and the photoresist material 73; next, as shown in FIG. 20, forming the second grating strips 11 of the antireflection layer 10 by patterning the absorption material layer 10′, where third gaps are formed between any two adjacent second grating strips 11 respectively.

At step 400, forming the second support layer 50 on the antireflection layer 10 includes: as shown in FIG. 21, filling the photoresist material 73 between any two adjacent second grating strips 11 of the antireflection layer 10 (that is, filling the photoresist material 73 in the third gaps formed between any two adjacent second grating strips 11) and curing the photoresist material 73 in such a way that an upper surface of the photoresist material 73 and an upper surface of the second grating strips 11 are located in a same horizontal plane; next, as shown in FIG. 22, forming a second support material layer on the upper surfaces of the second grating strips 11 and the photoresist material 73 and patterning the second support material layer to form the second support layer 50.

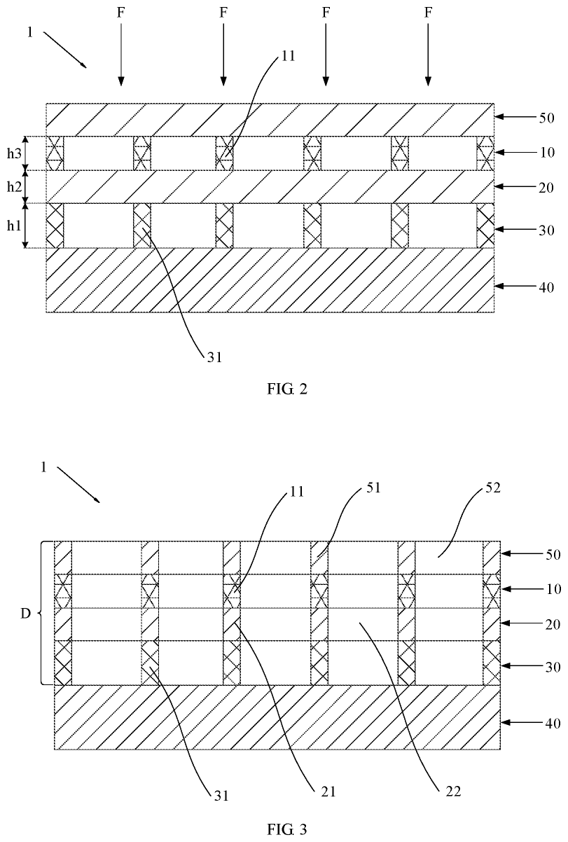

After all of the above steps are completed, the photoresist material 73 filled in different gaps (the first gaps 33, the second gaps and the third gaps 13) is washed off using a stripping solution to form the structure shown in FIG. 2.

It is to be noted that when the structure of the polarizer 1 not including the second support layer 50 is prepared, the structure of the polarizer 1 can be finally formed by washing off the photoresist material 73 filled in different gaps (the first gaps, the second gaps and the third gaps) using a stripping solution subsequent to completion of the step 300.

This embodiment further provides a display panel including the above polarizer.

This embodiment further provides a display apparatus including the above display panel.

### Embodiment 2

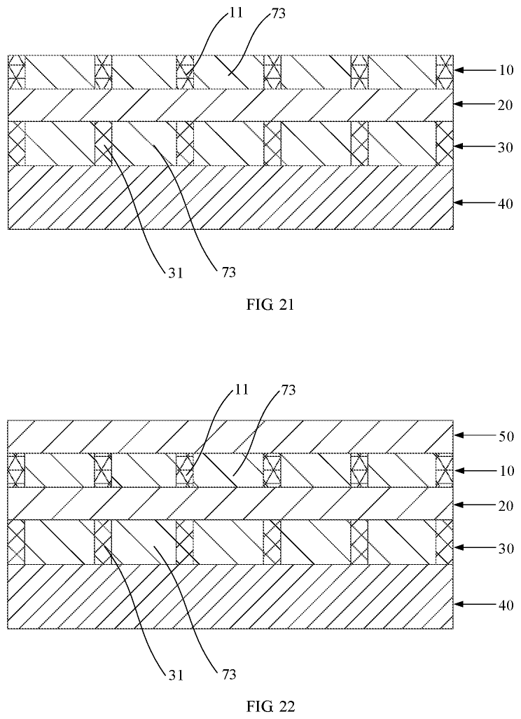

As shown in FIG. 23, the entire structure of the polarizer 1 of this embodiment is basically same as that of the embodiment 1 except that the polarizer 1 includes the substrate 40, the antireflection layer 10, the first support layer 20 and the grating layer 30 stacked in sequence along the light incidence direction. That is, the substrate 40 is located at a side of the antireflection layer 10 away from the first support layer 20.

Same as in the embodiment 1, in the first manner of achieving lowering of reflective index, the antireflection layer 10, the first support layer 20 and the grating layer 30 also form an optical resonant cavity structure. In the second manner, light reflected by the grating layer 30 can be directly absorbed by the antireflection layer 10 to achieve an effect of lowering reflective index.

In this embodiment, the specific position of the second support layer 50 is slightly different from the embodiment 1, that is, the second support layer 50 is located at a side of the antireflection layer 10 away from the first support layer 20 and between the substrate 40 and the antireflection layer 10. The second support layer 50 in this embodiment achieves the same effect as in the embodiment 1 and thus no redundant descriptions are made herein.

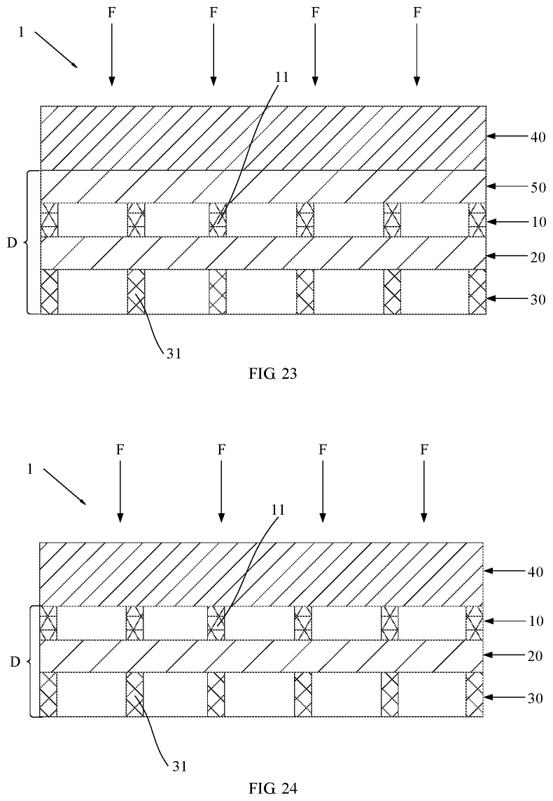

As shown in FIG. 24, in another implementation of the embodiment, the polarizer may not include the second support layer 50.

This embodiment further provides a polarizer manufacturing method used to prepare the above polarizer 1. The polarizer manufacturing method includes the following steps.

At step 100′, the second support layer is formed on the substrate.

At step 200′, the antireflection layer is formed on the substrate.

At step 300′, the first support layer is formed on the antireflection layer.

At step 400′, the grating layer is formed on the first support layer.

The specific processes of the above steps are same as in the embodiment 1 and will not be repeated herein.

When the polarizer 1 of this embodiment does not include the second support layer 50, the antireflection layer 10 may be directly formed on the substrate 40 without performing the step 100′ and then the subsequent steps are carried out.

The foregoing descriptions are merely illustrative of preferred embodiments of the present disclosure but not intended to limit the present disclosure, and any modifications, equivalent substitutions, adaptations thereof made within the spirit and principles of the disclosure shall be encompassed in the scope of protection of the present disclosure.

1. A polarizer, comprising
an antireflection layer, a first support layer and a grating layer stacked in sequence along a light incidence direction, wherein,
the grating layer comprises a plurality of first grating strips disposed along a first direction and the plurality of first grating strips are spaced apart;
the first support layer comprises a plurality of first support strips disposed along the first direction and spaced apart and a plurality of second support strips disposed between any two adjacent first support strips along a second direction, wherein the second direction and the first direction form an included angle which is greater than 0 degrees and smaller than 180 degrees, and the first support strips are disposed corresponding to the first grating strips;
the antireflection layer comprises a plurality of second grating strips disposed along the first direction, the plurality of second grating strips are spaced apart, and positions of the second grating strip are set corresponding to positions of the first grating strips; and
the antireflection layer, the first support layer and the grating layer form an optical resonant cavity structure, or, the antireflection layer is configured to absorb light reflected by the grating layer.

2. The polarizer according to claim 1, wherein the second direction is perpendicular to the first direction.

3. The polarizer according to claim 1, wherein a duty cycle of the grating layer is 0.3-0.6.

4. The polarizer according to claim 1, wherein along the light incidence direction, an orthographic projection of a first support strip is at least partially overlapped with an orthographic projection of a first grating strip corresponding to the first support strip, along the light incidence direction, an orthographic projection of a second grating strip is at least partially overlapped with an orthographic projection of a first grating strip corresponding to the second grating strip.

5. The polarizer according to claim 1, wherein the grating layer is made of a metal material; and the first support layer is made of a transparent material.

6. The polarizer according to claim 1, wherein the polarizer comprises a second support layer located at a side of the antireflection layer away from the first support layer, the second support layer comprises a plurality of third support strips disposed along the first direction and spaced apart and a plurality of fourth support strips disposed between any two adjacent third support strips along the second direction, and positions of the third support strips are set corresponding to positions of the first grating strips.

7. The polarizer according to claim 1, wherein the polarizer further comprises a substrate, and the substrate is located at a side of the grating layer away from the first support layer or at a side of the antireflection layer away from the first support layer.

8. A polarizer manufacturing method, used to prepare the polarizer according to claim 1 and the polarizer manufacturing method comprising:
forming the grating layer on a substrate;
forming the first support layer on the grating layer; and
forming the antireflection layer on the first support layer.

9. The polarizer manufacturing method according to claim 8, wherein after the antireflection layer is formed on the first support layer, the method further comprises:
forming a second support layer on the antireflection layer, wherein the second support layer comprises a plurality of third support strips disposed along the first direction and spaced apart and a plurality of fourth support strips disposed between any two adjacent third support strips along the second direction, and positions of the third support strips are set corresponding to positions of the first grating strips.

10. A polarizer manufacturing method, used to prepare the polarizer according to claim 1 and the polarizer manufacturing method comprising:
forming the antireflection layer on a substrate;
forming the first support layer on the antireflection layer; and
forming the grating layer on the first support layer.

11. The polarizer manufacturing method according to claim 10, wherein before the antireflection layer is formed on the substrate, the method further comprises:
forming a second support layer on the substrate, wherein the second support layer comprises a plurality of third support strips disposed along the first direction and spaced apart and a plurality of fourth support strips disposed between any two adjacent third support strips along the second direction, and positions of the third support strips are set corresponding to positions of the first grating strips.

12. A display panel, comprising the polarizer according to claim 1.

13. A display apparatus, comprising a display panel according to claim 12.

14. The polarizer according to claim 1, wherein
at least part of the second support strips located between different sets of two adjacent first support strips are located along a same straight line; or
the second support strips located between different sets of two adjacent first support strips are not located along a same straight line.

15. The polarizer according to claim 1, wherein
a height of the grating layer is greater than a height of the first support layer, and the height of the first support layer is greater than a height of the antireflection layer; and/or
the height of the grating layer is 100 nm-250 nm, the height of the first support layer is 70 nm-200 nm, and the height of the antireflection layer is 5 nm-100 nm.

16. The polarizer according to claim 4, wherein
along the light incidence direction, a distance of an orthographic projection of a side of the first support strip and an orthographic projection of a side of the first grating strip corresponding to the first support strip is smaller than or equal to 40 nm, and a distance of an orthographic projection of a side of the second grating strip and an orthographic projection of a side of the first grating strip corresponding to the second grating strip is smaller than or equal to 20 nm.

17. The polarizer according to claim 6, wherein the fourth support strips are disposed corresponding to the second support strips.

18. The polarizer according to claim 6, wherein the second support layer is made of a transparent material.

19. The polarizer manufacturing method according to claim 9, wherein the fourth support strips are disposed corresponding to the second support strips.

20. The polarizer manufacturing method according to claim 11, wherein the fourth support strips are disposed corresponding to the second support strips.
